(19) United States
(12) Patent Application Publication
(10) Pub. No.: US 2025/0293011 A1
(43) Pub. Date: Sep. 18, 2025

(54) PLASMA MONITORING METHOD AND SUBSTRATE PROCESSING METHOD USING THE SAME

(71) Applicant: SAMSUNG ELECTRONICS CO., LTD., Suwon-si (KR)

(72) Inventors: Minkyu SOHN, Suwon-si (KR); Chowon KANG, Suwon-si (KR); Euiseok KUM, Suwon-si (KR); Young-San PARK, Suwon-si (KR); Sejin OH, Suwon-si (KR)

(73) Assignee: SAMSUNG ELECTRONICS CO., LTD., Suwon-si (KR)

(21) Appl. No.: 18/809,954

(22) Filed: Aug. 20, 2024

(30) Foreign Application Priority Data
Mar. 13, 2024 (KR) 10-2024-0035095

(51) Int. Cl. H01J 37/32; G01J 3/443; H01L 21/67

(52) U.S. Cl. CPC H01J 37/32972; G01J 3/443; H01L 21/67253

(57) ABSTRACT

A plasma monitoring method may include measuring an optical signal emitted from plasma in a substrate processing apparatus and analyzing the optical signal. The analyzing of the optical signal may include analyzing a first optical signal, which is a portion of the optical signal and is emitted from a first material in the plasma. The first optical signal may include first, second, and third wavelength data on first, second, and third wavelength of light rays emitted from the first material. The analyzing of the first optical signal may include generating a first representative data that is representative of the first, second, and third wavelength data, calculating first, second, and third values, which are respectively given as correlation values between the first, second, and third wavelength data and the first representative data, and choosing a representative value of the first, second, and third values.

### CROSS-REFERENCE TO RELATED APPLICATIONS

This U.S. non-provisional patent application claims priority to Korean Patent Application No. 10-2024-0035095, filed on Mar. 13, 2024, in the Korean Intellectual Property Office, the entire contents of which is hereby incorporated by reference.

### BACKGROUND

### 1. Field

The present disclosure relates to a plasma monitoring method and a substrate processing method using the same, and in particular, to a plasma monitoring method of monitoring the stability of plasma and a substrate processing method using the same.

### 2. Description of Related Art

A process of fabricating a semiconductor device includes various processes. For example, the semiconductor device may be fabricated by performing a photolithography process, an etching process, a deposition process, and a plating process on a substrate. In the etching process and/or the deposition process, plasma may be generated on the substrate. During the process, the light emitted from the plasma may be measured to examine the state of the plasma.

### SUMMARY

Provided is a plasma monitoring method capable of monitoring stability of one material in plasma and a substrate processing method using the same.

Further, provided is a plasma monitoring method capable of monitoring a variation in the stability of the plasma, which occurs when the fabrication processes are sequentially performed on several substrates, and a substrate processing method using the same.

According to an aspect of the disclosure, a plasma monitoring method includes: measuring an optical signal emitted from plasma in a substrate processing apparatus, wherein the plasma comprises a first material, and wherein the optical signal comprises a first optical signal emitted from the first material; and analyzing the first optical signal, wherein the first optical signal includes: a first wavelength data on a first wavelength of light emitted from the first material; a second wavelength data on a second wavelength of the light emitted from the first material; and a third wavelength data on a third wavelength of the light emitted from the first material, and wherein the analyzing the first optical signal includes: generating first representative data that is representative of the first, the second, and the third wavelength data; obtaining a first value, a second value, and a third value, comprising respective correlation values between the first representative data and each of the first, the second, and the third wavelength data; and choosing a representative value from among the first, the second, and the third values.

According to an aspect of the disclosure, a plasma monitoring method includes: performing a first process on a first substrate in a substrate processing apparatus; performing a second process on a second substrate in the substrate processing apparatus; and comparing the first process with the second process, wherein the first process comprises obtaining first data on a first plasma generated in the substrate processing apparatus during the first process, wherein the second process comprises obtaining second data on a second plasma generated in the substrate processing apparatus during the second process, and wherein the comparing the first process with the second process comprises comparing the first data with the second data.

According to an aspect of the disclosure, a substrate processing method includes: performing a first process on a first substrate in a substrate processing apparatus, wherein the first process generates a first plasma; and monitoring the first plasma in the substrate processing apparatus, wherein the monitoring the first plasma comprises: measuring an optical signal emitted from the first plasma, wherein the first plasma comprises a first material, and the optical signal comprises a first optical signal emitted from the first material; and analyzing the first optical signal, and wherein the analyzing the first optical signal comprises: generating first representative wavelength data on a first representative wavelength, wherein the first representative wavelength is representative of a plurality of wavelengths of light emitted from the first material; obtaining respective correlation coefficients between wavelength data on the plurality of wavelengths of light and the first representative wavelength data; and choosing a smallest value from among the correlation coefficients as a representative value.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a sectional view illustrating a substrate processing apparatus according to an embodiment of the disclosure;

FIG. 2 is an enlarged sectional view illustrating a portion “X” of FIG. 1;

FIG. 3 is an enlarged sectional view illustrating a portion “Y” of FIG. 1;

FIG. 4 is a schematic diagram illustrating an analysis module according to an embodiment of the disclosure;

FIG. 5 is a flow chart illustrating a substrate processing method according to an embodiment of the disclosure;

FIG. 6 is a flow chart illustrating a plasma monitoring method according to an embodiment of the disclosure;

FIG. 7 is a flow chart illustrating a plasma monitoring method according to an embodiment of the disclosure;

FIGS. 8, 9, 10, 11 and 12 are sectional views illustrating a substrate processing method according to the flow chart of FIG. 5;

FIG. 13 is a graph showing a plurality of wavelengths of a light ray emitted from one material in plasma;

FIG. 14 is a graph showing a representative wavelength among a plurality of wavelengths of a light ray emitted from one material in plasma;

FIG. 15 is a matrix showing the correlation between a plurality of wavelengths of a light ray, which is emitted from one material in plasma, and a representative wavelength;

FIG. 16 is a matrix showing the correlation between representative wavelengths; and

FIG. 17 is a graph showing the stability of plasma.

### DETAILED DESCRIPTION

Example embodiments of the disclosure will now be described more fully with reference to the accompanying drawings, in which example embodiments are shown. Like reference numerals in the drawings denote like elements, and thus their description will be omitted.

Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection includes “connection via a wireless communication network”.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

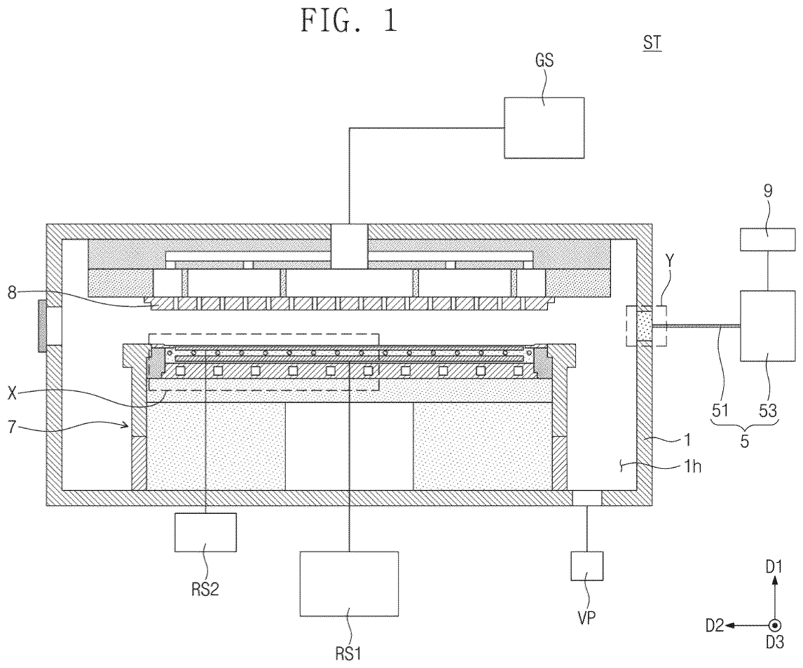

FIG. 1 is a sectional view illustrating a substrate processing apparatus according to an embodiment of the disclosure.

In the present application, the reference numbers D1, D2, and D3 will be used to denote a first direction, a second direction, and a third direction, respectively, which are not parallel to each other. The first direction D1 may be referred to as a vertical direction. In addition, each of the second and third directions D2 and D3 may be referred to as a horizontal direction.

Referring to FIG. 1, a substrate processing apparatus ST may be provided. The substrate processing apparatus ST may be configured to treat a substrate using plasma. More specifically, the substrate processing apparatus ST may be used to perform an etching process and/or a deposition process on the substrate. As used herein, the term “substrate” may mean a silicon wafer, but the disclosure is not limited to this example. The substrate processing apparatus ST may be configured to generate plasma. The substrate processing apparatus ST may be configured to generate the plasma in various manners. For example, the substrate processing apparatus ST may be a capacitively coupled plasma (CCP) apparatus and/or an inductively coupled plasma (ICP) apparatus. The description that follows refers to the CCP apparatus, for brevity's sake, but the disclosure is not limited to this example. The substrate processing apparatus ST may include a process chamber 1, a stage 7, a shower head 8, a window 3 (e.g., see FIG. 3), a DC power generating device RS2, a RF power generating device RS1, a vacuum pump VP, a gas supplying device GS, an optical measurement module 5, and an analysis module 9.

The process chamber 1 may be configured to provide a process space 1h. The process space 1h may be used to perform a fabrication process on a substrate. The process space 1h may be isolated from the external space. During the fabrication process on the substrate, the process space 1h may be in a substantially vacuum state. The process chamber 1 may have a shape such as a circular pipe or cylinder, but the disclosure is not limited to this example.

The stage 7 may be placed in the process chamber 1. That is, the stage 7 may be placed in the process space 1h. The stage 7 may be configured to support and/or hold the substrate. The fabrication process may be performed on the substrate, which is loaded on the stage 7. The stage 7 will be described in more detail below.

The shower head 8 may be placed in the process chamber 1. That is, the shower head 8 may be placed in the process space 1h. The shower head 8 may be spaced apart from the stage 7 in an upward direction. The shower head 8 may be configured to provide a gas hole. The gas supplied from the gas supplying device GS may be sprayed into the process space 1h through the shower head 8.

The window 3 (e.g., see FIG. 3) may be combined with the process chamber 1. The window 3 will be described in more detail below.

The DC power generating device RS2 may be configured to apply a DC power to the stage 7. The DC power from the DC power generating device RS2 may be used to fasten the substrate to a specific position on the stage 7.

The RF power generating device RS1 may be configured to supply an RF power to the stage 7. Accordingly, it may be possible to generate and/or control the plasma in the process space 1h. This will be described in more detail below.

The vacuum pump VP may be connected to the process space 1h. The vacuum pump VP may be used to maintain the process space 1h at a vacuum pressure, during the fabrication process on the substrate.

The gas supplying device GS may be configured to supply a gas into the process space 1h. For this, the gas supplying device GS may include a gas tank, a compressor, and a valve. A portion of the gas, which is supplied into the process space 1h by the gas supplying device GS, may be used to form the plasma.

The optical measurement module 5 may be configured to measure the plasma in the substrate processing apparatus ST. For this, the optical measurement module 5 may be connected to the substrate processing apparatus ST. The optical measurement module 5 may be configured to measure light emitted from the plasma in the substrate processing apparatus ST. For this, the optical measurement module 5 may include a light delivery device 51 and an optical emission spectrometry (OES) 53. The light delivery device 51 may be coupled to the substrate processing apparatus ST. The OES 53 may be connected to the light delivery device 51. The OES 53 may be configured to send information, which is received through the light delivery device 51, to the analysis module 9.

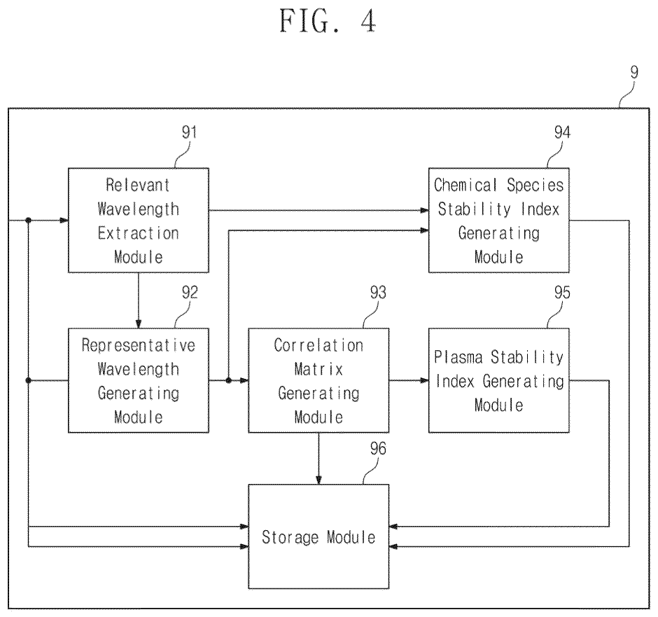

The analysis module 9 may be used to analyze the information on the plasma measured by the optical measurement module 5. In other words, the analysis module 9 may be used to analyze the information received from the optical measurement module 5. For this, the analysis module 9 may include a computer. The analysis module 9 will be described in more detail with reference to FIG. 4.

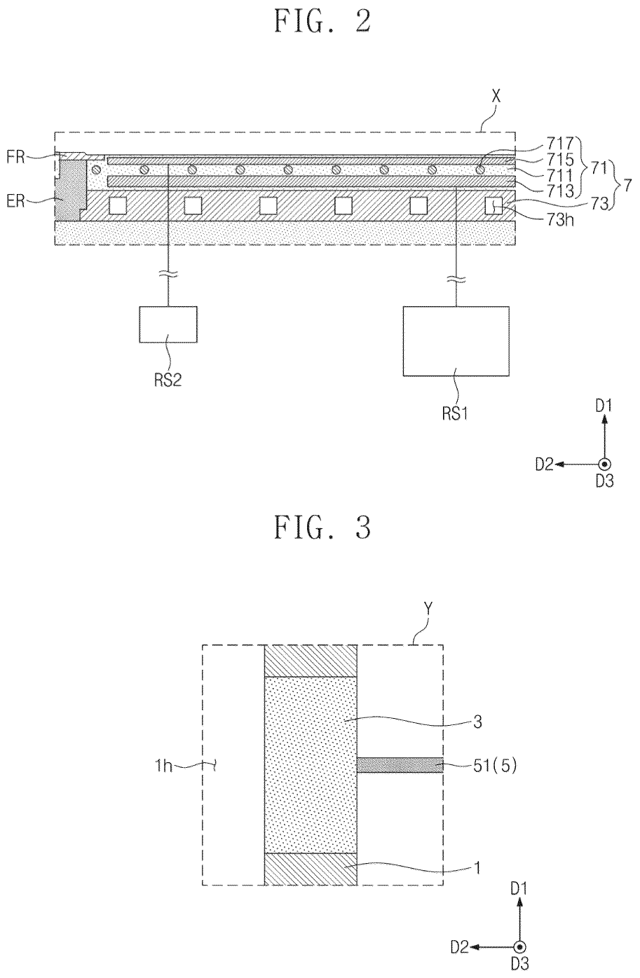

FIG. 2 is an enlarged sectional view illustrating a portion “X” of FIG. 1.

Referring to FIG. 2, the stage 7 may include a chuck 71 and a cooling plate 73.

The substrate may be disposed on the chuck 71. The chuck 71 may be configured to fasten the substrate to a specific position. For this, the chuck 71 may include a chuck body 711, a plasma electrode 713, a chuck electrode 715, and a heater 717.

The chuck body 711 may have a shape such as a circular pipe or cylinder. The chuck body 711 may be formed of or include a ceramic material, but the disclosure is not limited to this example. The substrate may be disposed on a top surface of the chuck body 711. A focus ring FR and/or an edge ring ER may be provided to enclose the chuck body 711.

The plasma electrode 713 may be placed in the chuck body 711. The plasma electrode 713 may be formed of or include aluminum (Al). The plasma electrode 713 may have a circular-plate shape, but the disclosure is not limited to this example. An RF power may be applied to the plasma electrode 713. More specifically, the RF power generating device RS1 may be configured to apply an RF power to the plasma electrode 713. The plasma in the process space 1h (e.g., see FIG. 1) may be controlled by the RF power applied to the plasma electrode 713.

The chuck electrode 715 may be placed in the chuck body 711. The chuck electrode 715 may be placed at a level higher than the plasma electrode 713. A DC power may be applied to the chuck electrode 715. More specifically, the DC power generating device RS2 may be configured to apply a DC power to the chuck electrode 715. The substrate on the chuck body 711 may be fastened to a specific position by the DC power applied to the chuck electrode 715. The chuck electrode 715 may be formed of or include aluminum (Al), but the disclosure is not limited to this example.

The heater 717 may be placed in the chuck body 711. The heater 717 may be placed between the chuck electrode 715 and the plasma electrode 713. The heater 717 may include a heating line. For example, the heater 717 may include a heating line provided in a concentric manner. The heater 717 may dissipate heat energy toward neighboring elements. Accordingly, the chuck body 711 or the like may be heated.

The cooling plate 73 may be placed below the chuck 71. That is, the chuck 71 may be placed on the cooling plate 73. The cooling plate 73 may be configured to provide a cooling hole 73h. Cooling water may flow through the cooling hole 73h. The cooling water in the cooling hole 73h may absorb heat energy from the cooling plate 73.

FIG. 3 is an enlarged sectional view illustrating a portion “Y” of FIG. 1.

Referring to FIG. 3, the window 3 may be provided in a sidewall of the process chamber 1. Light in the process space 1h may be incident into the external space outside the process chamber 1 through the window 3.

The light delivery device 51 may be coupled to the substrate processing apparatus ST. For example, the light delivery device 51 may be coupled to the window 3. The light delivery device 51 may be configured to deliver light, which is emitted from the plasma in the process space 1h, to the OES 53 (e.g., see FIG. 1). For this, the light delivery device 51 may include, for example, an optical cable or the like, but the disclosure is not limited to this example.

FIG. 4 is a schematic diagram illustrating an analysis module according to an embodiment of the disclosure.

Referring to FIG. 4, the analysis module 9 may include a relevant wavelength extraction module 91, a representative wavelength generating module 92, a correlation matrix generating module 93, a chemical species stability index generating module 94, a plasma stability index generating module 95, and a storage module 96.

The relevant wavelength extraction module 91 may be configured to extract a relevant wavelength from a light ray, which is emitted from the plasma in the process space 1h (e.g., see FIG. 1), through the optical measurement module 5 (e.g., see FIG. 1). The relevant wavelength may mean a wavelength of a light ray emitted from a specific material, which is one of a plurality of materials in the plasma and is chosen as a target material. That is, the relevant wavelength extraction module 91 may extract a wavelength, which is associated with the light ray emitted from the target material in the plasma, from the spectrum of the plasma. The light ray emitted from the target material may have a line or absorption spectrum at a plurality of wavelengths. In an embodiment, the light ray emitted from the target material may have a nonvanishing or non-negligible intensity at three wavelengths.

The representative wavelength generating module 92 may be configured to generate a representative wavelength. The representative wavelength may refer to a wavelength that is representative of the light ray emitted from the target material in the plasma. The generation of the representative wavelength may be achieved through various methods. For example, the representative wavelength generating module 92 may generate the representative wavelength through the principal component analysis (PCA). However, the disclosure is not limited to this example, and the representative wavelength may be generated through other methods (e.g., using machine learning). This will be described in more detail below.

The correlation matrix generating module 93 may be configured to generate a correlation matrix. The correlation matrix may be generated to represent the correlation between the representative wavelength and a plurality of wavelengths. In an embodiment, the correlation value may refer to a correlation coefficient, but the disclosure is not limited to this example. This will be described in more detail below.

The chemical species stability index generating module 94 may be configured to choose a representative value as an index representing the stability of one material in the plasma. For example, the chemical species stability index generating module 94 may generate the stability of the one material in the plasma, using the correlation matrix. This will be described in more detail below.

The plasma stability index generating module 95 may be configured to choose a plasma stability index as an index representing the overall stability of all of the materials in the plasma. The plasma stability index may be used to evaluate the stability of the plasma. This will be described in more detail below.

The storage module 96 may be configured to store data, which are generated by the relevant wavelength extraction module 91, the representative wavelength generating module 92, the correlation matrix generating module 93, the chemical species stability index generating module 94, and the plasma stability index generating module 95.

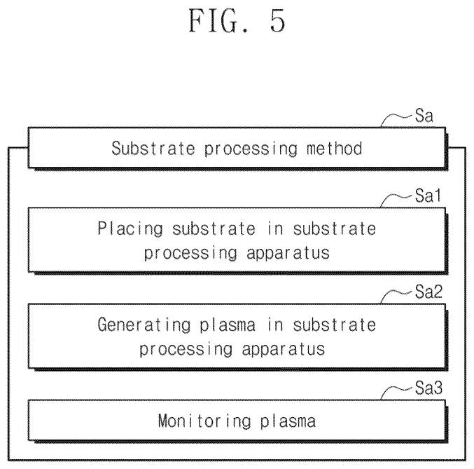

FIG. 5 is a flow chart illustrating a substrate processing method according to an embodiment of the disclosure.

Referring to FIG. 5, a substrate processing method Sa may be provided. The substrate processing method Sa may be a method of processing a substrate, using the substrate processing apparatus ST (e.g., of FIG. 1) described with reference to FIGS. 1 to 4. The substrate processing method Sa may include placing a substrate in a substrate processing apparatus (in Sa1), generating plasma in the substrate processing apparatus (in Sa2), and monitoring the plasma (in Sa3). This will be described in more detail below.

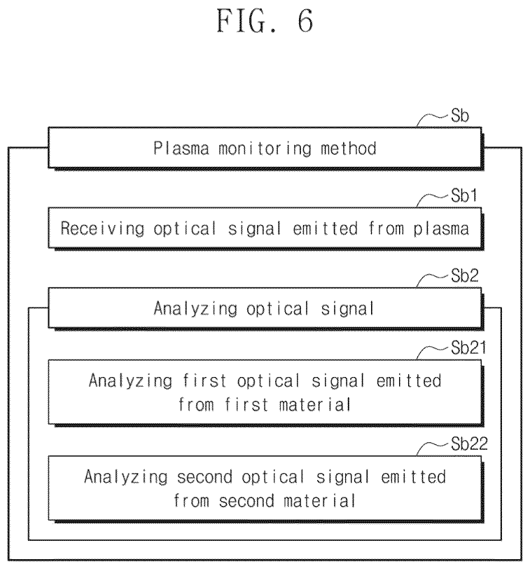

FIG. 6 is a flow chart illustrating a plasma monitoring method according to an embodiment of the disclosure.

Referring to FIG. 6, a plasma monitoring method Sb may be provided. The plasma monitoring method Sb may be a method of monitoring plasma in the substrate processing apparatus ST (e.g., of FIG. 1). More specifically, the plasma monitoring method Sb may be a method of monitoring the plasma described with reference to FIG. 5 (in Sa3). The plasma monitoring method Sb may include receiving an optical signal emitted from the plasma (in Sb1) and analyzing the optical signal (in Sb2).

The analyzing of the optical signal (in Sb1) may include analyzing a first optical signal emitted from a first material (in Sb21) and analyzing a second optical signal emitted from a second material (in Sb22). This will be described in more detail below.

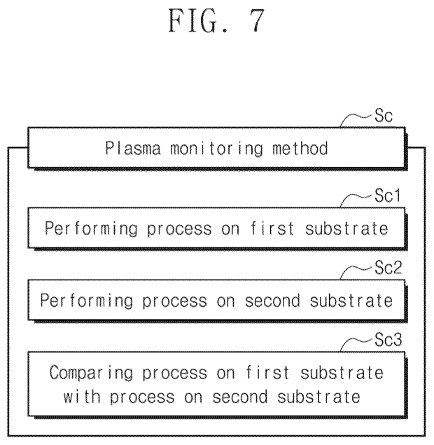

FIG. 7 is a flow chart illustrating a plasma monitoring method according to an embodiment of the disclosure.

Referring to FIG. 7, a plasma monitoring method Sc may be provided. The plasma monitoring method Sc may be used to monitor the physical state of plasma, which is generated in the substrate processing apparatus ST (e.g., of FIG. 1) when the fabrication processes are performed on a plurality of substrates. For this, the plasma monitoring method Sc may include performing a process on a first substrate (in Sc1), performing a process on a second substrate (in Sc2), and comparing the process on the first substrate with the process on the second substrate (in Sc3). This will be described in more detail below.

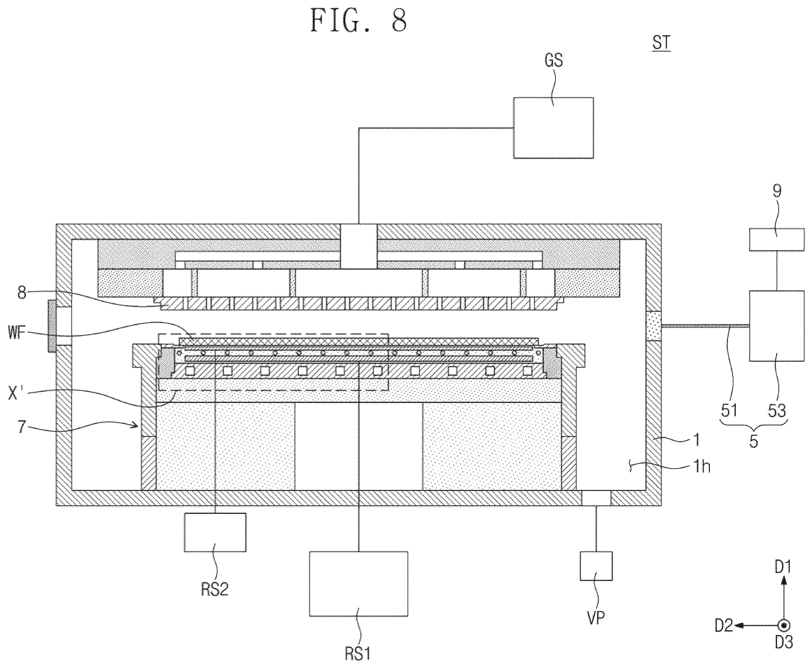

FIGS. 8 to 12 are sectional views illustrating a substrate processing method according to the flow chart of FIG. 5.

Referring to FIGS. 8, 9, and 5, the placing of the substrate in the substrate processing apparatus (in Sa1) may include placing a substrate WF on the stage 7. The substrate WF may be placed on the chuck 71, and then a DC power may be applied to the chuck electrode 715 from the DC power generating device RS2. Thus, the substrate WF may be fixed to a specific position on the stage 7.

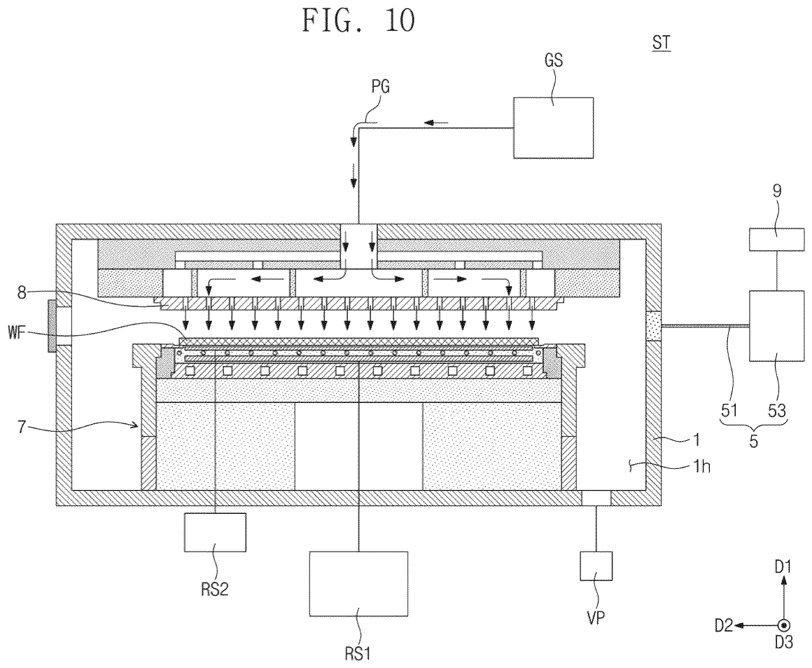

Referring to FIGS. 10 and 5, the generating of the plasma in the substrate processing apparatus (in Sa2) may include supplying a process gas PG into the substrate processing apparatus ST. More specifically, the process gas PG may be supplied into the process space 1h from the gas supplying device GS.

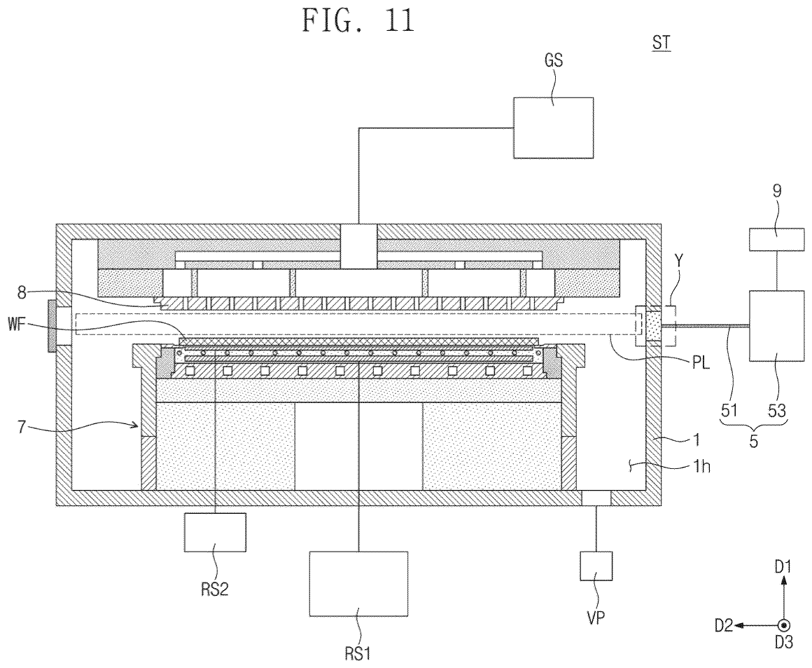

Referring to FIGS. 11 and 5, the generating of the plasma in the substrate processing apparatus (in Sa2) may include generating plasma PL in the process space 1h from at least a portion of the process gas PG (e.g., see FIG. 10), using the RF power applied to the stage 7 from the RF power generating device RS1. The substrate WF on the stage 7 may be processed or treated by the plasma PL in the process space 1h. For example, the plasma PL may be used to form a deposition layer on the substrate WF or etch the deposition layer or the substrate WF.

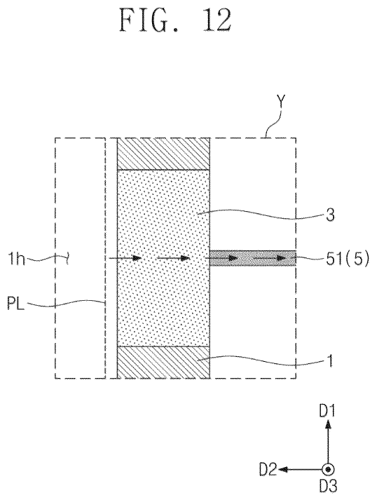

Referring to FIGS. 12 and 6, the receiving of the optical signal emitted from the plasma (in Sb1) may include receiving an optical signal, which is emitted from the plasma PL in the process space 1h and is incident into the OES 53 (e.g., see FIG. 11) through the window 3 and the light delivery device 51. The optical signal, which is incident into the OES 53, may be transmitted to the analysis module 9 (e.g., see FIG. 11). The analysis module 9 may be configured to analyze the transmitted optical signal and evaluate the stability of the plasma. Hereinafter, a method of analyzing the optical signal using the analysis module 9 will be described in more detail with reference to FIGS. 13 to 17.

FIG. 13 is a graph showing a plurality of wavelengths of a light ray emitted from one material in plasma.

Referring to FIG. 13, the horizontal axis represents time. That is, the unit of the horizontal axis is second (sec). The vertical axis represents an intensity of light measured.

Referring to FIGS. 13 and 6, the analyzing of the first optical signal emitted from the first material (in Sb21) may include extracting a plurality of wavelength data from the first optical signal. The first optical signal may include a plurality of wavelength data. For example, the first optical signal may include a first wavelength data on a first wavelength, a second wavelength data on a second wavelength, and a third wavelength data on a third wavelength. In an embodiment, the first material may include one of Ar, CF, CF₂, CO, CO₂, F, O, O₂, or SiF₂.

Three lines in the graph of FIG. 13 shows the change in time of light intensity at three distinct wavelengths. For example, in the case where the first material includes argon (Ar), each of the three lines in the graph of FIG. 13 shows the change in time of the intensity of a light ray emitted from argon plasma at three distinct wavelengths in the argon spectrum. More specifically, the 434.8 line shows the change in time of the intensity at the wavelength of 434.8 nm. This will be referred to as the first wavelength data. The 476.5 line shows the change in time of the intensity at the wavelength of 476.5 nm. This will be referred to as the second wavelength data. The 488 line shows the change in time of the intensity at the wavelength of 488 nm. This will be referred to as the third wavelength data. As described above, the spectrum of the argon plasma may be examined at three distinct wavelengths. The time-varying intensity behavior of the argon plasma measured at the three wavelengths may be different from each other. This process may be performed by the relevant wavelength extraction module 91 (e.g., see FIG. 4).

The embodiment described above refers to an example, in which the spectrum of light emitted from one material are measured at three wavelengths, but the disclosure is not limited to this example. That is, the spectrum of light emitted from one material in the plasma may be examined at two wavelengths or at four or more wavelengths. In addition, the embodiment described above refers to an example, in which the argon (Ar) is chosen as the target material, but the disclosure is not limited to this example. In other words, another material in the plasma may be chosen to create the graph. For example, the graph may be obtained from a light ray emitted from one of CF, CF₂, CO, CO₂, F, O, O₂, or SiF₂ in the plasma.

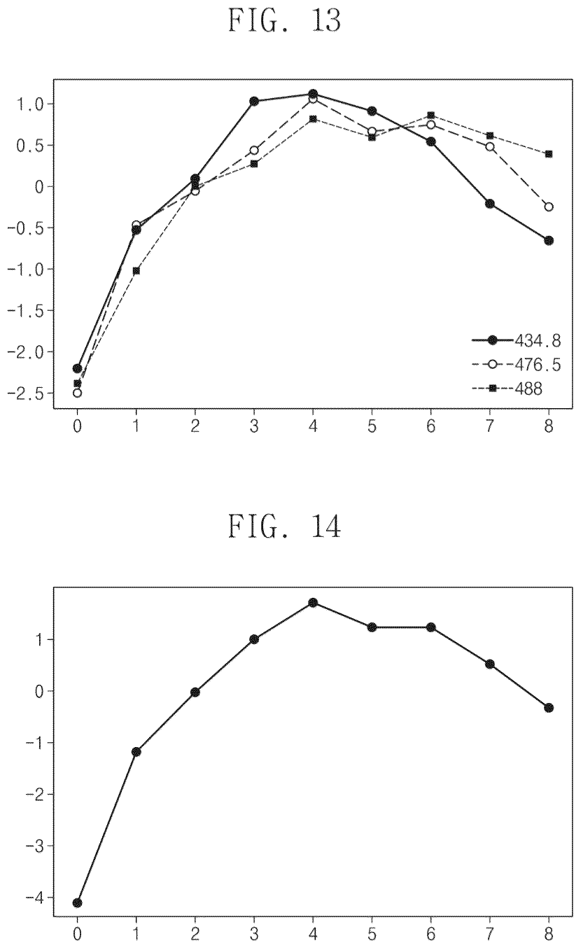

FIG. 14 is a graph showing a representative wavelength among a plurality of wavelengths of a light ray emitted from one material in plasma.

Referring to FIG. 14, the horizontal axis represents time. That is, the unit of the horizontal axis is second (sec). The vertical axis represents an intensity of measured light.

Referring to FIGS. 14 and 6, the analyzing of the first optical signal emitted from the first material (in Sb21) may include generating first representative data, which is representative of the first, second, and third wavelength data. The line in the graph of FIG. 14 shows the first representative data. The first representative data shows the change in time of an intensity of the light ray at the representative wavelength. The representative wavelength may be representative of a first wavelength, a second wavelength, and a third wavelength. The representative wavelength may be generated by the principal component analysis (PCA). However, the disclosure is not limited to this example, and the representative wavelength may be generated by other methods (e.g., a machine learning method). This process may be performed by the representative wavelength generating module 92 (e.g., see FIG. 4).

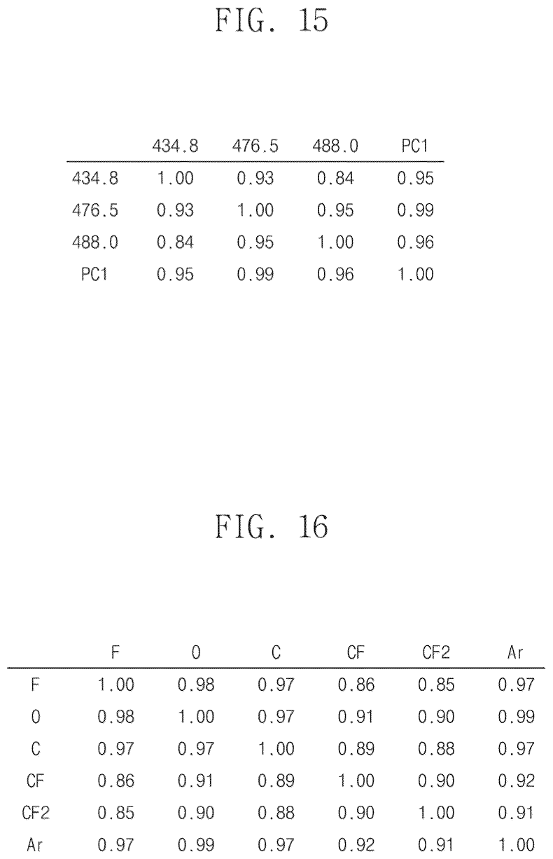

FIG. 15 is a matrix showing a correlation between a plurality of wavelengths of a light ray, which is emitted from one material in plasma, and a representative wavelength.

Referring to FIG. 15, the correlation matrix may be provided. The correlation matrix of FIG. 15 may be a matrix showing correlation values between the representative wavelength described with reference to FIGS. 13 and 14 and a plurality of wavelengths. The correlation value may be calculated through various methods. For example, the correlation value may be given as the Euclidean distance or the correlation coefficient or may be calculated using the dynamic time warping (DTW) method. Hereinafter, for brevity's sake, the correlation value will be assumed to be the correlation coefficient.

A correlation value between the first wavelength data and the first representative data may be calculated as a first value. The first value may be, for example, 0.95. A correlation value between the second wavelength data and the first representative data may be calculated as a second value. The second value may be, for example, 0.99. A correlation value between the third wavelength data and the first representative data may be calculated as a third value. The third value may be, for example, 0.96. This process may be performed by the correlation matrix generating module 93 (e.g., see FIG. 4).

Referring to FIGS. 15 and 6, the analyzing of the first optical signal emitted from the first material (in Sb21) may include choosing a representative value. The representative value may be a value that is representative of the first value, the second value, and the third value. More specifically, the representative value may be the smallest value among the first value, the second value, and the third value. If the representative value is small, it may be interpreted that the first material in the plasma is unstable. This process may be performed by the chemical species stability index generating module 94 (e.g., see FIG. 4).

Referring back to FIG. 6, the plasma monitoring method Sb may further include generating an alert signal, when the representative value is smaller than a threshold value. For example, if the representative value of FIG. 15 is smaller than the threshold value, an alert signal may be generated. In the case where the alert signal is generated, an operation of modifying the process recipe or a preservative maintenance (PM) operation may be performed.

Referring to FIG. 6, the analyzing of the second optical signal emitted from the second material (in Sb22) may include performing the above process on the second material in the plasma. The second material may be different from the first material. The embodiment refers to an example, in which the evaluation of stability is executed on two materials, but the disclosure is not limited to this example. For example, the evaluation of stability may be executed on one material or each of three or more materials.

In a plasma monitoring method according to an embodiment of the disclosure and a substrate processing method including the same, all wavelengths of light emitted from one material in the plasma may be considered to evaluate the stability of the material in the plasma. Thus, it may be possible to accurately monitor the stability of the material in the plasma.

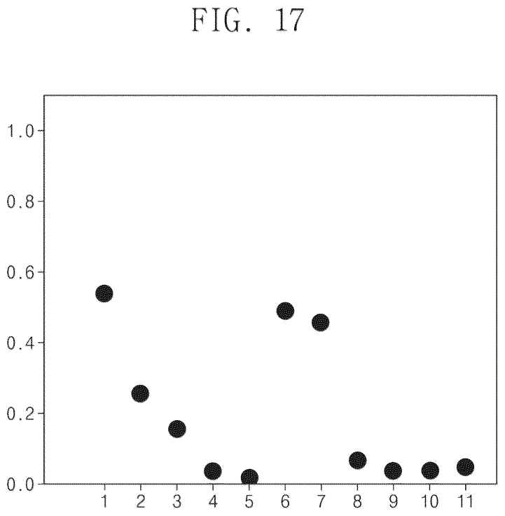

FIG. 16 is a matrix showing a correlation between representative wavelengths.

Referring to FIG. 7, the process on the first substrate (in Sc1) may be performed in the same or similar manner as that described with reference to FIGS. 8 to 11. For example, the process described with reference to FIGS. 8 to 12 may be performed on the first substrate. More specifically, the first substrate may be disposed in the substrate processing apparatus ST (e.g., see FIG. 8), and then, the process gas PG (e.g., see FIG. 10) may be supplied into the process space 1h (e.g., see FIG. 10) to perform the process on the first substrate. First data on the plasma PL (e.g., see FIG. 11) in the substrate processing apparatus ST, in which the process on the first substrate is performed, may be obtained during this process.

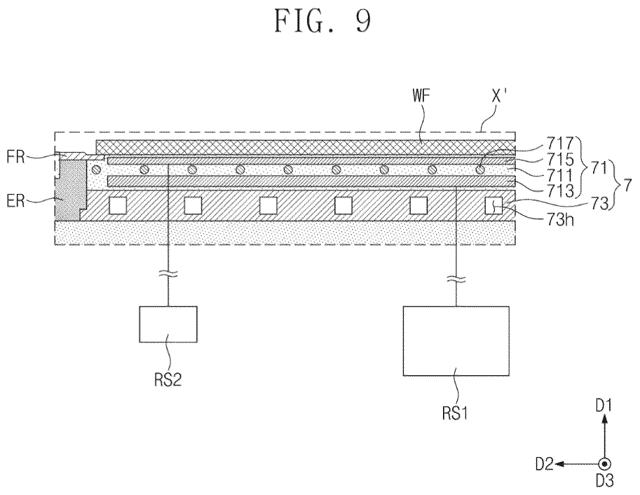

The process on the second substrate (in Sc2) may be performed after the process on the first substrate (in Sc1) is finished. The process on the second substrate (in Sc2) may include performing the process described with reference to FIGS. 8 to 12 on the second substrate. More specifically, the second substrate may be placed in the substrate processing apparatus ST (e.g., see FIG. 8), and then, the process on the second substrate may be performed by supplying the process gas PG (e.g., see FIG. 9) into the process space 1h (e.g., see FIG. 9). Second data on the plasma PL (e.g., see FIG. 11) in the substrate processing apparatus ST, in which the process on the second substrate is performed, may be obtained during this process.

Referring to FIGS. 7 and 16, the obtaining of the first data may include obtaining a first matrix, which is a correlation matrix between wavelengths of light rays emitted from several materials, respectively, in the plasma. A representative wavelength for each of the materials in the plasma may be generated to obtain the first matrix. For example, if three materials are present in the plasma, a first representative wavelength, a second representative wavelength, and a third representative wavelength may be generated. The first representative wavelength may refer to a wavelength that is representative of a plurality of wavelengths of a light ray emitted from the first material. This process may be the same or similar to that described with reference to FIGS. 13 and 14. The second representative wavelength may refer to a wavelength that is representative of a plurality of wavelengths of a light ray emitted from the second material. The third representative wavelength may refer to a wavelength that is representative of a plurality of wavelengths of a light ray emitted from the third material. Next, the first matrix, which is a correlation matrix between the first, second, and third representative wavelengths, may be generated. The above embodiment refers to an example, in which the correlation matrix for the three materials is generated, but the disclosure is not limited to this example. For example, the correlation matrix may be generated for two materials or four or more materials. Alternatively, as shown in FIG. 16, the correlation matrix may be generated for six materials, such as F, O, C, CF, CF₂, and Ar, in the plasma. The second data may be obtained by performing a process substantially similar to the process used for obtaining the first data, during the fabrication process on the second substrate. As a result, a second matrix may be generated.

The comparing of the processes on the first and second substrates (Sc3) may include calculating a difference between the first matrix and the second matrix to generate a comparison matrix. The comparison matrix may be obtained by subtracting the first matrix from the second matrix. The largest value in the comparison matrix may be referred to as a stability index. The stability index may represent the difference in plasma state between the process performed on the first substrate and the process performed on the second substrate. If the large stability index may mean that there is a large difference in plasma state between the process performed on the first substrate and the process performed on the second substrate. That is, the large stability index may mean that the plasma is not uniform. This process may be performed by the plasma stability index generating module 95 (e.g., see FIG. 4).

When the stability index is greater than a threshold value, the plasma monitoring method Sc may further include generating an alert signal. That is, when the stability index described with reference to FIG. 16 is greater than the threshold value, the alert signal may be generated. In the case where the alert signal is generated, an operation of modifying the process recipe or a preservative maintenance (PM) operation may be performed.

The above embodiment refers to an example, in which the process is performed on two substrates, but the disclosure is not limited to this example. That is, the same process may be further performed on a third substrate. In this case, the process on the second substrate may be compared with the process on the third substrate.

FIG. 17 is a graph showing the stability of plasma.

Referring to FIG. 17, the horizontal axis represents the order of the process performed. For example, the value 1 on the horizontal axis represents the comparison between the process on the first substrate and the process on the second substrate. The value 2 on the horizontal axis represents the comparison between the process on the second substrate and the process on the third substrate. The vertical axis may represent the value of the stability index. That is, the graph of FIG. 17 shows the change of the stability index, which occurs when the process is repeated on several substrates.

In a plasma monitoring method according to an embodiment of the disclosure and a substrate processing method including the same, by comparing the results of the processes performed on several substrates, it may be possible to monitor the stability of the plasma. That is, it may be possible to monitor the stability of the plasma generated during a process performed on one substrate, as well as to enable comparison and analysis across multiple processes performed sequentially.

In a plasma monitoring method according to an embodiment of the disclosure and a substrate processing method using the same, it may be possible to monitor the stability of one material in plasma.

In a plasma monitoring method according to an embodiment of the disclosure and a substrate processing method using the same, it may be possible to monitor a variation in the stability of the plasma, which occurs when the fabrication processes are sequentially performed on several substrates.

While example embodiments of the disclosure have been particularly shown and described, it will be understood by one of ordinary skill in the art that variations in form and detail may be made therein without departing from the spirit and scope of the attached claims.

What is claimed is:

1. A plasma monitoring method comprising:
measuring an optical signal emitted from plasma in a substrate processing apparatus, wherein the plasma comprises a first material, and wherein the optical signal comprises a first optical signal emitted from the first material; and
analyzing the first optical signal, wherein the first optical signal comprises:
a first wavelength data on a first wavelength of light emitted from the first material;
a second wavelength data on a second wavelength of the light emitted from the first material; and
a third wavelength data on a third wavelength of the light emitted from the first material, and
wherein the analyzing the first optical signal comprises:
generating first representative data that is representative of the first, the second, and the third wavelength data;
obtaining a first value, a second value, and a third value, comprising respective correlation values between the first representative data and each of the first, the second, and the third wavelength data; and
choosing a representative value from among the first, the second, and the third values.

2. The plasma monitoring method of claim 1,
wherein the first wavelength data comprises data representing a time-varying intensity behavior of the light of the first wavelength, and
wherein the first value is a correlation coefficient between the first wavelength data and the first representative data.

3. The plasma monitoring method of claim 2, wherein the choosing the representative value comprises choosing a smallest value from among the first, the second, and the third values as the representative value.

4. The plasma monitoring method of claim 1, wherein the first material comprises one of Ar, CF, CF₂, CO, CO₂, F, O, O₂, or SiF₂.

5. The plasma monitoring method of claim 1, further comprising:
based on the representative value being smaller than a threshold value, generating an alert signal.

6. The plasma monitoring method of claim 5, further comprising:
based on the alert signal being generated, changing a process recipe utilized by the substrate processing apparatus or performing preservative maintenance on the substrate processing apparatus.

7. The plasma monitoring method of claim 1, wherein the generating the first representative data comprises performing a principal component analysis.

8. The plasma monitoring method of claim 1,
wherein the wherein the plasma comprises a second material different from the first material,
wherein the optical signal comprises a second optical signal emitted from the second material, and
wherein the plasma monitoring method further comprises analyzing the second optical signal.

9. The plasma monitoring method of claim 1, wherein the first material comprises argon (Ar),
the first wavelength is 434.8 nm,
the second wavelength is 476.5 nm, and
the third wavelength is 488.0 nm.

10. A plasma monitoring method comprising:
performing a first process on a first substrate in a substrate processing apparatus;
performing a second process on a second substrate in the substrate processing apparatus; and
comparing the first process with the second process,
wherein the first process comprises obtaining first data on a first plasma generated in the substrate processing apparatus during the first process,
wherein the second process comprises obtaining second data on a second plasma generated in the substrate processing apparatus during the second process, and
wherein the comparing the first process with the second process comprises comparing the first data with the second data.

11. The plasma monitoring method of claim 10,
wherein the obtaining the first data comprises generating a first matrix, wherein the first matrix comprises a correlation matrix between wavelengths of light emitted from one or more materials in the first plasma, and
the obtaining the second data comprises generating a second matrix, wherein the second matrix comprises a correlation matrix between wavelengths of light emitted from one or more materials in the second plasma.

12. The plasma monitoring method of claim 11, wherein the comparing the first with the second data comprises:
generating a comparison matrix by obtaining a difference between the first matrix and the second matrix; and
choosing a largest value in the comparison matrix as a stability index.

13. The plasma monitoring method of claim 12, further comprising:
based on the stability index being greater than a threshold value, generating an alert signal.

14. The plasma monitoring method of claim 11, wherein the generating the first matrix comprises:
generating a first representative wavelength, wherein the first representative wavelength is representative of a plurality of wavelengths of light emitted from a first material in the first plasma;
generating a second representative wavelength, wherein the second representative wavelength is representative of a plurality of wavelengths of light emitted from a second material in the first plasma;
generating a third representative wavelength, wherein the third representative wavelength is representative of a plurality of wavelengths of light emitted from a third material in the first plasma; and
generating the first matrix, wherein the first matrix comprises a correlation matrix between the first representative wavelength, the second representative wavelength, and the third representative wavelength.

15. The plasma monitoring method of claim 14, wherein the generating the first representative wavelength comprises performing a principal component analysis on the plurality of wavelengths of light emitted from the first material.

16. The plasma monitoring method of claim 10, further comprising:
performing a third process on a third substrate in the substrate processing apparatus; and
comparing the second process with the third process.

17. A substrate processing method comprising:
performing a first process on a first substrate in a substrate processing apparatus, wherein the first process generates a first plasma; and
monitoring the first plasma in the substrate processing apparatus,
wherein the monitoring the first plasma comprises:
measuring an optical signal emitted from the first plasma, wherein the first plasma comprises a first material, and the optical signal comprises a first optical signal emitted from the first material; and
analyzing the first optical signal, and
wherein the analyzing the first optical signal comprises:
generating first representative wavelength data on a first representative wavelength, wherein the first representative wavelength is representative of a plurality of wavelengths of light emitted from the first material;
obtaining respective correlation coefficients between wavelength data on the plurality of wavelengths of light and the first representative wavelength data; and
choosing a smallest value from among the correlation coefficients as a representative value.

18. The substrate processing method of claim 17, wherein the generating the first representative wavelength data on the first representative wavelength comprises performing a principal component analysis.

19. The substrate processing method of claim 17, further comprising:
performing a second process on a second substrate in the substrate processing apparatus, wherein the second process generates a second plasma;
monitoring the second plasma in the substrate processing apparatus; and
comparing the first process with the second process,
wherein the comparing of the first and the second processes comprises comparing first data obtained from the first plasma with second data obtained from the second plasma.

20. The substrate processing method of claim 17, wherein the measuring the optical signal emitted from the first plasma comprises measuring the optical signal through a window in a portion of a process chamber of the substrate processing apparatus.
